(19) United States
(12) Patent Application Publication
(10) Pub. No.: US 2016/0268181 A1
(43) Pub. Date: Sep. 15, 2016

(54) SEMICONDUCTOR DEVICE

(71) Applicant: KABUSHIKI KAISHA TOSHIBA, Tokyo (JP)

(72) Inventor: Norio Yasuhara, Kawasaki Kanagawa (JP)

(21) Appl. No.: 14/837,710

(22) Filed: Aug. 27, 2015

(30) Foreign Application Priority Data
Mar. 10, 2015 (JP) 2015-046868

(51) Int. Cl. H01L 23/373; H01L 29/417; H01L 29/739; H01L 29/49; H01L 29/861; H01L 29/423; H01L 29/51

(52) U.S. Cl. CPC H01L 23/3736; H01L 29/4236; H01L 29/41708; H01L 29/51; H01L 29/495; H01L 29/8611; H01L 29/7397

(57) ABSTRACT

A semiconductor device according to an embodiment includes a first electrode, a second electrode, a semiconductor portion connected between the first electrode and the second electrode, and a third electrode disposed in the interior of the semiconductor portion, made of metal, spaced from the first electrode, and connected to the second electrode.

### CROSS-REFERENCE TO RELATED APPLICATIONS

This application is based upon and claims the benefit of priority from Japanese Patent Application No. 2015-046868, filed on Mar. 10, 2015; the entire contents of which are incorporated herein by reference.

### FIELD

Embodiments relate to a semiconductor device.

### BACKGROUND

In the related art, semiconductor devices for power control, such as a power diode, a power metal-oxide-semiconductor field-effect transistor (MOSFET), an insulated gate bipolar transistor (IGBT), and an injection enhanced gate transistor (IEGT), are developed and put into practical use. However, when a current flows to the semiconductor device, heat is generated in the interior of the semiconductor device, and the temperature of the semiconductor device rises. Especially when a load short-circuit situation occurs, such as when a load is broken from any cause, the heat generation is increased because of a high voltage applied to the semiconductor device, and thus there is a problem that the semiconductor device suffers thermal breakdown in some cases.

### BRIEF DESCRIPTION OF THE DRAWINGS

FIG. 1 is a plan view showing a semiconductor device according to a first embodiment;

FIG. 2 is a cross-sectional view showing the semiconductor device according to the first embodiment;

FIG. 3 is a cross-sectional view showing a semiconductor device according to a second embodiment;

FIG. 4 is a plan view showing a semiconductor device according to a third embodiment;

FIG. 5 is a cross-sectional view showing the semiconductor device according to the third embodiment;

FIG. 6 is a cross-sectional view showing a semiconductor device according to a fourth embodiment;

FIG. 7 is a cross-sectional view showing a semiconductor device according to a fifth embodiment; and

FIG. 8 is an equivalent circuit diagram showing the semiconductor device according to the fifth embodiment.

### DETAILED DESCRIPTION

A semiconductor device according to an embodiment includes a first electrode, a second electrode, a semiconductor portion connected between the first electrode and the second electrode, and a third electrode disposed in the interior of the semiconductor portion, made of metal, spaced from the first electrode, and connected to the second electrode.

### First Embodiment

First, a first embodiment will be described.

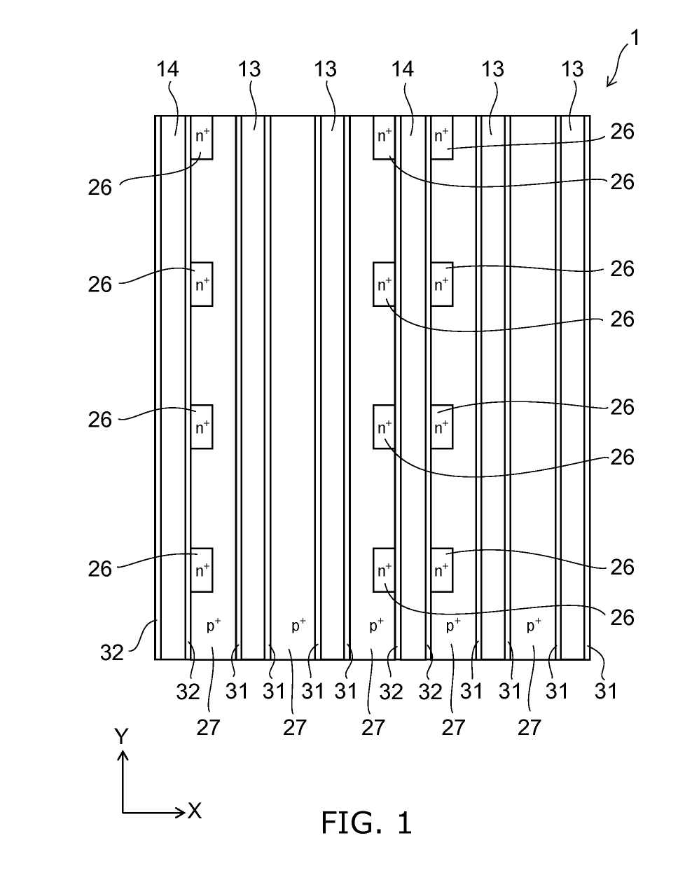

FIG. 1 is a plan view showing a semiconductor device according to the embodiment.

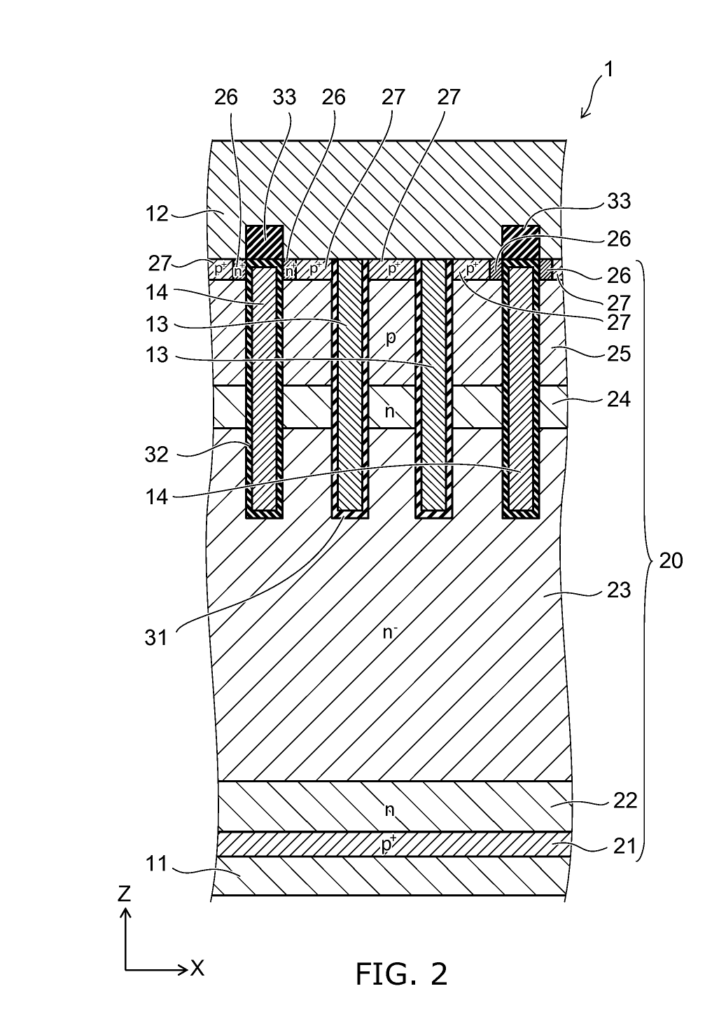

FIG. 2 is a cross-sectional view showing the semiconductor device according to the embodiment.

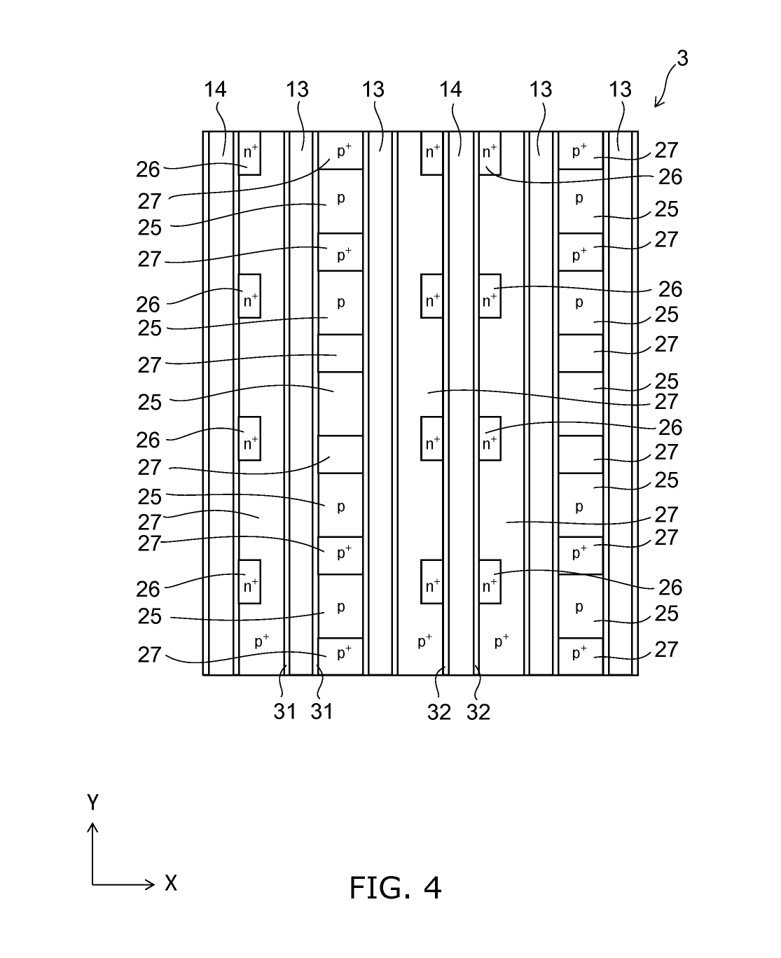

As shown in FIG. 1 and FIG. 2, the semiconductor device 1 according to the embodiment is an IEGT. In the semiconductor device 1 (hereinafter also referred to as simply as “device 1”), a plate-like collector electrode 11 is provided, and a plate-like emitter electrode 12 is provided parallel to and spaced from the collector electrode 11. The collector electrode 11 and the emitter electrode 12 are made of metal, and, for example, made of stacked metal mainly containing aluminum (Al), an aluminum-silicon alloy (Al—Si), copper (Cu), nickel (Ni), or the like. In FIG. 1, the emitter electrode 12 is not shown. The same applies to FIG. 4 described later.

A silicon portion 20 made of a semiconductor material, for example, single-crystal silicon (Si) is provided between the collector electrode 11 and the emitter electrode 12, and connected between the collector electrode 11 and the emitter electrode 12. Hereinafter, for convenience of description, a direction from the collector electrode 11 toward the emitter electrode 12 is referred to as “top (upper side)”, and the opposite direction is referred to as “bottom (lower side)”. However, these directions have no relation to the direction of gravity. Moreover, in the specification, an XYZ orthogonal coordinate system is adopted for convenience of description. The upward direction from the collector electrode 11 toward the emitter electrode 12 is also referred to as “Z-direction”, and two directions parallel to the upper surface of the collector electrode 11 and orthogonal to each other are referred to as “X-direction” and “Y-direction”.

In the silicon portion 20, a p⁺-type collector layer 21, an n-type buffer layer 22, an n⁻-type drift layer 23, an n-type base layer 24, and a p-type base layer 25 are stacked in this order from the bottom to the top. The p⁺-type collector layer 21 is provided on the entire surface of the collector electrode 11, and connected to the collector electrode 11. An n⁺-type emitter layer 26 is provided on a portion of the p-type base layer 25. Moreover, a p⁺-type contact layer 27 is provided on another portion of the p-type base layer 25. The n⁺-type emitter layer 26 and the p⁺-type contact layer 27 are in contact with each other. The n⁺-type emitter layer 26 and the p⁺-type contact layer 27 are in contact with the emitter electrode 12, and thus connected to the emitter electrode 12.

In the specification, for example, the expression “p⁺-type collector layer 21” shows that the conductivity type of the layer is p-type. The same applies to n-type. Moreover, the superscripts “+” and “−” relatively show effective impurity concentrations. For example, as to the layer whose conductivity type is n-type, “n⁺-type”, “n-type”, and “n⁻-type” denote the effective impurity concentrations in descending order. Further, the “effective impurity concentration” refers to the concentration of an impurity that contributes to conduction of a semiconductor material. When a certain portion includes both an impurity serving as a donor and an impurity serving as an acceptor, the “effective impurity concentration” refers to the concentration of the amount excluding the amount of offset between the donor and the acceptor. An impurity serving as a donor for silicon is, for example, phosphorus (P), while an impurity serving as an acceptor is, for example, boron (B).

A plurality of trench dummy electrodes 13 are provided in the upper portion of the silicon portion 20. The trench dummy electrodes 13 are arranged along the X-direction, and extend in the Y-direction. The trench dummy electrode 13 is formed of metal, for example, tungsten, and, for example, is in contact with the emitter electrode 12. Hence, the trench dummy electrode 13 is electrically and thermally connected to the emitter electrode 12, and electrical and thermal contact resistances between the trench dummy electrode 13 and the emitter electrode 12 are small.

The upper end portion of the trench dummy electrode 13 is in contact with the p⁺-type contact layer 27 via an insulating film 31 described later; the intermediate portion of the trench dummy electrode 13 is in contact with the p-type base layer 25 and the n-type base layer 24 via the insulating film 31; and the lower end portion of the trench dummy electrode 13 is located in the n⁻-type drift layer 23. Hence, the trench dummy electrode 13 does not reach the collector electrode 11, and is spaced from the collector electrode 11. The insulating film 31 made of, for example, silicon oxide is provided around the trench dummy electrode 13, that is, between the trench dummy electrode 13 and the silicon portion 20. Due to this, the trench dummy electrode 13 is spaced from the silicon portion 20.

Moreover, a plurality of trench gate electrodes 14 are provided in the upper portion of the silicon portion 20. The trench gate electrodes 14 are arranged along the X-direction, and extend in the Y-direction. In the device 1, the trench dummy electrodes 13 and the trench gate electrodes 14 are arranged periodically along the X-direction. For example, one trench gate electrode 14 is provided every two trench dummy electrodes 13. The trench gate electrode 14 is formed of a conductive material, for example, polysilicon. The trench gate electrode 14 may be formed of metal such as tungsten. In the upper surface of the silicon portion 20, the n⁺-type emitter layer 26 is discontinuously disposed along the Y-direction on both sides of the trench gate electrode 14 in the X-direction. Moreover, a region that is not the n⁺-type emitter layer 26 in the upper surface of the silicon portion 20 is the p⁺-type contact layer 27. For this reason, the upper end portion of the trench gate electrode 14 is in contact with the n⁺-type emitter layer 26 and the p⁺-type contact layer 27 via a gate insulating film 32 described later; the intermediate portion of the trench gate electrode 14 is in contact with the p-type base layer 25 and the n-type base layer 24 via the gate insulating film 32; and the lower end portion of the trench gate electrode 14 is located in the n⁻-type drift layer 23. In the Z-direction, the lower edge of the trench gate electrode 14 is located at substantially the same position as the lower edge of the trench dummy electrode 13. Moreover, in the X-direction, the width of the trench gate electrode 14 is substantially equal to the width of the trench dummy electrode 13.

The gate insulating film 32 made of, for example, silicon oxide is provided around the trench gate electrode 14. The gate insulating film 32 intervenes between the trench gate electrode 14 and the silicon portion 20. Moreover, an insulating member 33 made of, for example, silicon oxide is provided on the silicon portion 20 and in a region directly on the trench gate electrode 14. Due to this, the trench gate electrode 14 is insulated from the silicon portion 20, the collector electrode 11, the emitter electrode 12, and the trench dummy electrode 13.

Next, the operation of the semiconductor device 1 according to the embodiment will be described.

When a positive potential not less than a threshold is applied to the trench gate electrode 14, an inversion layer is formed in the vicinity of the gate insulating film 32 in the p-type base layer 25. In this state, when a voltage is applied to the emitter electrode 12 so as to render the collector electrode 11 positive, electrons flow from the n⁺-type emitter layer 26 through the inversion layer into the n-type base layer 24, the n⁻-type drift layer 23, and the n-type buffer layer 22. Then, a p-n junction between the n-type buffer layer 22 and the p⁺-type collector layer 21 is forward biased, electrons flow from the n-type buffer layer 22 into the p⁺-type collector layer 21, and holes flow from the p⁺-type collector layer 21 into the n-type buffer layer 22, so that a current flows. Due to this, the device 1 is brought into ON state.

In this case, since the trench dummy electrode 13 at the same potential as the emitter electrode 12 is arranged together with the trench gate electrode 14, the potential gradient is small in a region interposed between the trench dummy electrode 13 and the trench gate electrode 14. Therefore, the holes flowing from the collector electrode 11 into the silicon portion 20 tend not to flow to the emitter electrode 12 and are stored in the upper portion of the silicon portion 20. Due to this, the injection of electrons from the emitter electrode 12 into the silicon portion 20 is enhanced, and as a result, a large current is allowed to flow through the device 1. On the other hand, by making the potential of the trench gate electrode 14 less than the threshold, the inversion layer can be eliminated in the p-type base layer 25, and the device 1 can be brought into OFF state.

However, with the flow of the current through the device 1, heat is inevitably generated in the device 1. Especially when a load connected to the device 1 is short-circuited during the ON state of the device 1 and a large current flows therethrough, a larger amount of heat is generated. When the temperature of the device 1 rises, a potential barrier at a p-n junction surface between the n⁺-type emitter layer 26 and the p-type base layer 25 decreases. Hence, if the temperature of the device 1 rises excessively, the potential barrier decreases excessively, which increases electrons directly flowing from the n⁺-type emitter layer 26 to the p-type base layer 25 without through the inversion layer, creating a vicious circle in which the current flowing through the device 1 further increases, the temperature further rises, the potential barrier further decreases, and the current further increases. As a result of this, the current flowing through the device 1 cannot be controlled, so that the device 1 may experience thermal breakdown.

In the embodiment, therefore, the trench dummy electrode 13 made of metal is embedded in the silicon portion 20, and connected to the emitter electrode 12, so that the heat generated in the silicon portion 20 is released to the emitter electrode 12 via the trench dummy electrode 13. When the trench dummy electrode 13 is formed of, for example, tungsten, the trench dummy electrode 13 has high heat dissipation property because tungsten has a thermal conductivity appropriately the same as that of silicon at a room temperature but has a larger thermal conductivity than that of silicon at a high temperature. As a result of this, the temperature rise of the silicon portion 20 can be suppressed, the creation of the vicious circle described above can be avoided, and thus the thermal breakdown of the device 1 can be prevented. Especially by forming the trench dummy electrode 13 deep in the silicon portion 20, a temperature rise at a p-n junction interface between the n⁺-type emitter layer 26 and the p-type base layer 25 is effectively controlled, so that a reduction in potential barrier can be effectively controlled. According to the embodiment as described above, it is possible to realize the semiconductor device that is less likely to experience thermal breakdown.

Moreover, since the trench dummy electrode 13 is in contact with the emitter electrode 12 in the embodiment, a thermal resistance is small between the trench dummy electrode 13 and the emitter electrode 12. Due to this, the heat generated in the silicon portion 20 can be discharged more effectively to the emitter electrode 12. The insulating film 31 around the trench dummy electrode 13 is thin similarly to the gate insulating film 32, a thermal resistance due to the insulating film 31 is small.

Further, in the embodiment, the trench dummy electrode 13 is provided between the trench gate electrodes 14 to limit the outflow of holes from the silicon portion 20 to the emitter electrode 12, so that the injection of electrons from the emitter electrode 12 to the silicon portion 20 is enhanced and thus a larger current is allowed to flow through the device.

The ratio of the number of trench dummy electrodes 13 to the number of trench gate electrodes 14 is not limited to 2 to described above, and may be selected depending on characteristics required for the device 1. For example, gate capacitances between the trench gate electrode 14, and the emitter electrode 12 and the collector electrode 11 can be reduced as the ratio of the trench dummy electrode 13 increases, which is advantageous when the operating frequency of the device 1, that is, the frequency of a signal input to the trench gate electrode 14 is high.

Moreover, the material of the trench dummy electrode 13 is not limited to tungsten, and may be other metal. For example, metal having a high thermal conductivity such as copper (Cu) or aluminum (Al) is favorably used.

### Second Embodiment

Next, a second embodiment will be described.

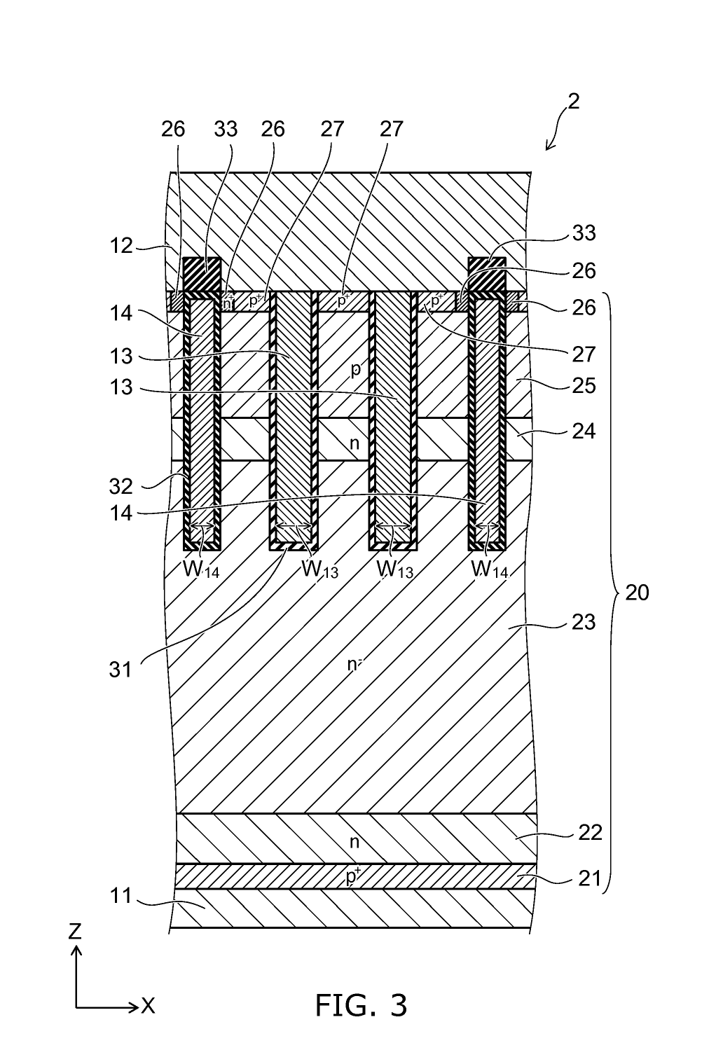

FIG. 3 is a cross-sectional view showing a semiconductor device according to the embodiment.

As shown in FIG. 3, the semiconductor device 2 according to the embodiment differs from the semiconductor the device 1 (refer to FIG. 2) according to the first embodiment in that a width W₁₃ of the trench dummy electrode 13 in the X-direction is thicker than a width W₁₄ of the trench gate electrode 14.

According to the embodiment, the width W₁₃ of the trench dummy electrode 13 is made thicker than the width W₁₄ of the trench gate electrode 14, so that the thermal resistance of the trench dummy electrode 13 is further reduced and thus heat discharge efficiency can be further enhanced.

The configuration, operation, and advantageous effect of the embodiment other than those described above are the same as those of the first embodiment.

### Third Embodiment

Next, a third embodiment will be described.

FIG. 4 is a plan view showing a semiconductor device according to the embodiment.

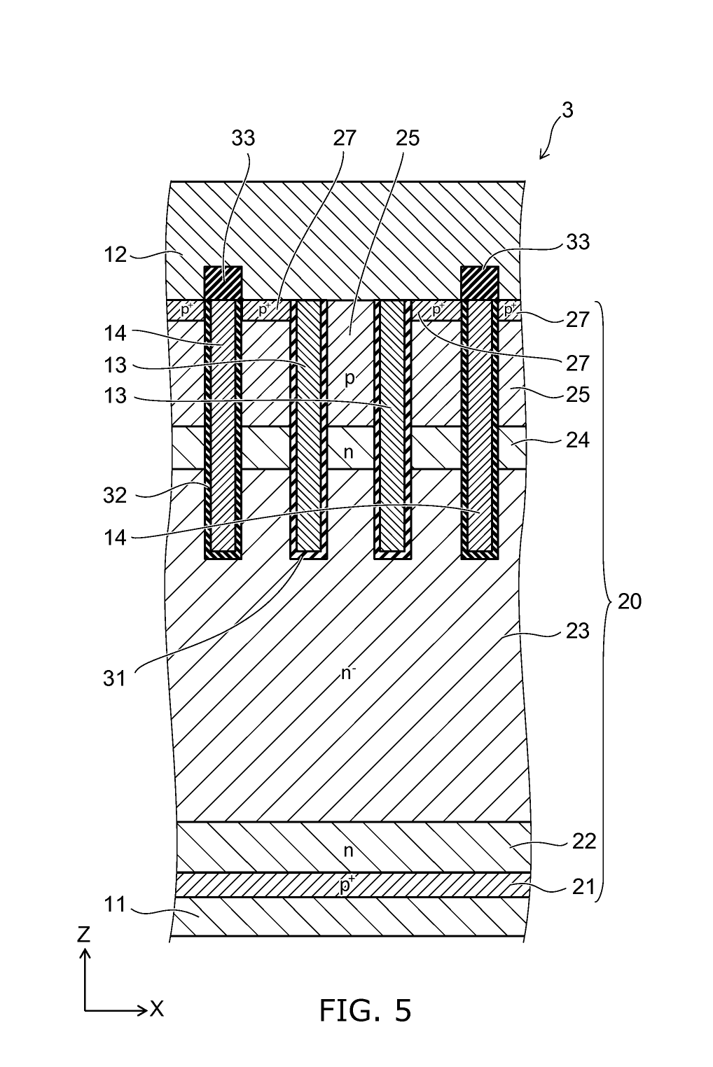

FIG. 5 is a cross-sectional view showing the semiconductor device according to the embodiment.

As shown in FIG. 4 and FIG. 5, the p-type base layer 25 is exposed in a portion of the upper surface of the silicon portion 20 in the semiconductor device 3 according to the embodiment. Specifically, in the upper surface of the silicon portion 20, the n⁺-type emitter layer 26 is discontinuously disposed along the Y-direction on both sides of the trench gate electrode 14 in regions each between the trench gate electrode 14 and the trench dummy electrode 13, and a region that is not the n⁺-type emitter layer 26 is the p⁺-type contact layer 27. Moreover, the p⁺-type contact layer 27 is discontinuously disposed along the Y-direction in a region between the trench dummy electrodes 13, and the p-type base layer 25 is exposed in regions where the p⁺-type contact layer 27 is not present.

For this reason, the upper end portion of the trench dummy electrode 13 is opposed to the p-type base layer 25 and the p⁺-type contact layer 27 via the insulating film 31, and the trench gate electrode 14 is opposed to the n⁺-type emitter layer 26 and the p⁺-type contact layer 27 via the gate insulating film 32.

### Fourth Embodiment

Next, a fourth embodiment will be described.

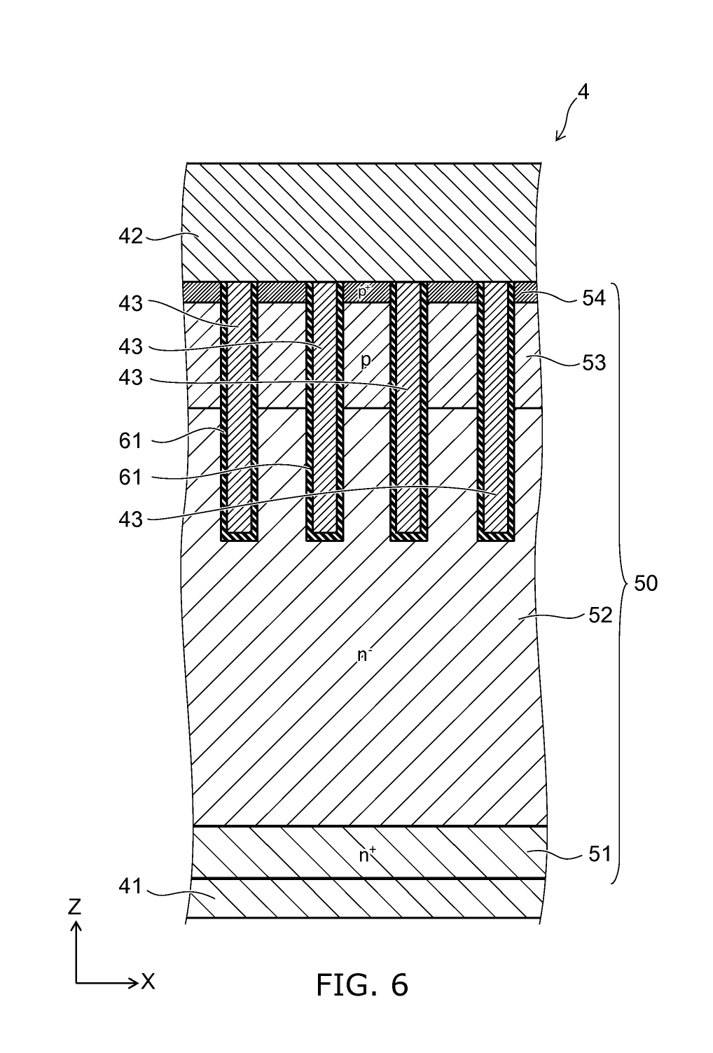

FIG. 6 is a cross-sectional view showing a semiconductor device according to the embodiment.

As shown in FIG. 6, the semiconductor device 4 according to the embodiment is a p-n diode. In the semiconductor device 4, a plate-like cathode electrode 41 is provided, and a plate-like anode electrode 42 is provided parallel to and spaced from the cathode electrode 41. The cathode electrode 41 and the anode electrode 42 are made of metal, and, for example, made of aluminum or an aluminum-silicon alloy. In the embodiment, a direction from the cathode electrode 41 toward the anode electrode 42 is referred to as “top (upper side)” or “Z-direction”, and the opposite direction is referred to as “bottom (lower side)”.

A silicon portion 50 made of a semiconductor material, for example, single-crystal silicon is provided between the cathode electrode 41 and the anode electrode 42, and connected between the cathode electrode 41 and the anode electrode 42. In the silicon portion 50, an n⁺-type cathode layer 51, an n⁻-type buffer layer 52, a p-type anode layer 53, and a p⁺-type contact layer 54 are stacked in this order from the bottom to the top. The n⁺-type cathode layer 51 is provided on the entire surface of the cathode electrode 41, in contact with the cathode electrode 41, and thus connected to the cathode electrode 41. The p⁺-type contact layer 54 is in contact with the anode electrode 42, and thus connected to the anode electrode 42.

A plurality of trench electrodes 43 are provided in the upper portion of the silicon portion 50. The trench electrodes 43 are arranged, for example, periodically along the X-direction, and extend in the Y-direction. The trench electrode 43 is formed of metal, for example, tungsten, and in contact with the anode electrode 42. Hence, the trench electrode 43 is electrically and thermally connected with a low resistance to the anode electrode 42.

The upper end portion of the trench electrode 43 is located in the p⁺-type contact layer 54; the intermediate portion of the trench electrode 43 is located in the p-type anode layer 53; and the lower end portion of the trench electrode 43 is located in the n⁻-type buffer layer 52. The trench electrode 43 does not reach the cathode electrode 41, and is spaced from the cathode electrode 41. An insulating film 61 made of, for example, silicon oxide is provided between the trench electrode 43 and the silicon portion 50. Due to the insulating film 61, the trench electrode 43 is spaced from the silicon portion 50.

Next, the operation of the semiconductor device 4 according to the embodiment will be described.

The semiconductor device 4 is a p-n diode, which allows a current flowing from the anode electrode 42 to the cathode electrode 41 to flow but blocks a current flowing from the cathode electrode 41 to the anode electrode 42. Similarly to the first embodiment, heat is generated in the silicon portion 50 with the flow of the current. Moreover, with the temperature rise of the silicon portion 50, a potential barrier at a p-n junction surface between the n⁻-type buffer layer 52 and the p-type anode layer 53 decreases, so that the current flows more easily. Due to this, if a state in which a high voltage is applied in the forward direction is brought about, and when the vicious circle described in the first embodiment is created, the current cannot be controlled and thus the device 3 may experience thermal breakdown.

In the embodiment, therefore, the trench electrode 43 made of metal and connected to the anode electrode 42 is embedded in the silicon portion 50. Due to this, the heat in the silicon portion 50 is efficiently discharged to the anode electrode 42 via the trench electrode 43. Moreover, by forming the trench electrode 43 monolithically with the anode electrode 42, a thermal resistance between the electrodes is further reduced. Further, by causing the trench electrode 43 to reach a p-n junction surface between the n⁻-type buffer layer 52 and the p-type anode layer 53, the p-n junction surface is effectively cooled, and thus a reduction in potential barrier is more effectively controlled.

### Fifth Embodiment

Next, a fifth embodiment will be described.

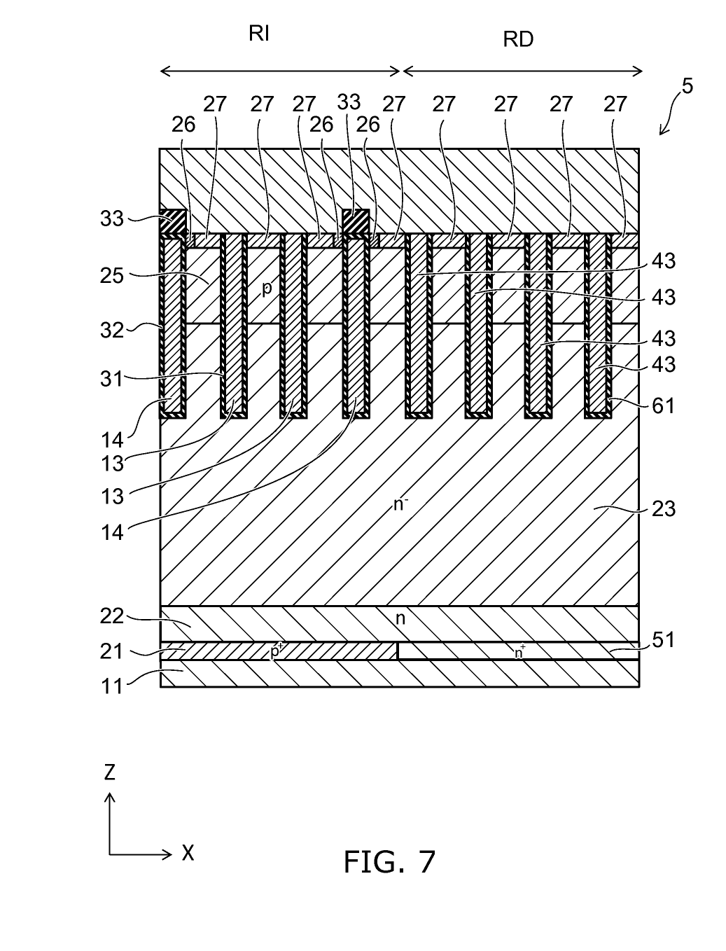

FIG. 7 is a cross-sectional view showing a semiconductor device according to the embodiment.

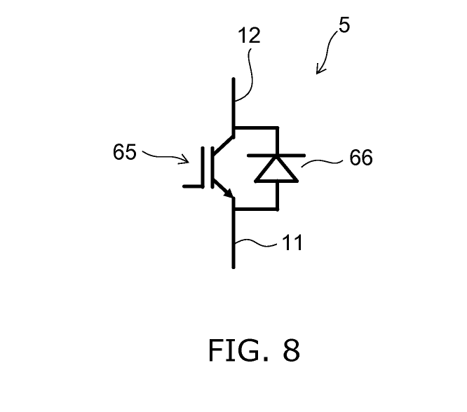

FIG. 8 is an equivalent circuit diagram showing the semiconductor device according to the embodiment.

As shown in FIG. 7, an IGBT region RI and a diode region RD are disposed along the X-direction in the semiconductor device 5 according to the embodiment. The IGBT region RI and the diode region RD share the collector electrode 11 and the emitter electrode 12. That is, in the diode region RD, the collector electrode 11 functions as a cathode electrode, and the emitter electrode 12 functions as an anode electrode.

The configuration of the IGBT region RI is substantially the same as that of the semiconductor device 1 (refer to FIG. 2) according to the first embodiment. However, the n-type base layer 24 is not provided in the semiconductor device 5. The n-type base layer 24 may be provided in the IGBT region RI. On the other hand, the configuration of the diode region RD is substantially the same as that of the semiconductor device 4 (refer to FIG. 6) according to the fourth embodiment. However, the n-type buffer layer 22 is provided on the n⁺-type cathode layer 51 in the semiconductor device 5. In FIG. 7, reference numerals of portions in the diode region RD are consistent with those used in the first embodiment (refer to FIG. 2).

Due to this, as shown in FIG. 8, an IGBT 65 formed in the IGBT region RI and a diode 66 formed in the diode region RD are connected in reverse parallel with each other between the collector electrode 11 and the emitter electrode 12 in the semiconductor device 5 to thereby configure a reverse conducting IGBT.

According to the embodiment, the IGBT 65 and the diode 66 can be provided in one chip. The configuration, operation, and advantageous effect of the embodiment other than those described above are the same as those of the first embodiment and the fourth embodiment.

Although an example in which the semiconductor device is an IEGT or a p-n diode has been shown in the embodiments, the invention is not limited to this example. For example, the semiconductor device may be an IGBT or a power MOSFET.

According to the embodiments described above, it is possible to realize the semiconductor device that is less likely to experience thermal breakdown.

While certain embodiments of the invention have been described, these embodiments have been presented by way of example only, and are not intended to limit the scope of the invention. Indeed, the novel embodiments described herein may be embodied in a variety of other forms; furthermore, various omission, substitutions, and changes in the form of the embodiments described herein may be made without departing from the spirit of the invention. The accompanying claims and their equivalents are intended to cover such forms or modifications as would fall within the scope and spirit of the invention.

What is claimed is:

1. A semiconductor device comprising:
a first electrode;
a second electrode;
a semiconductor portion connected between the first electrode and the second electrode; and
a third electrode disposed in the interior of the semiconductor portion, made of metal, spaced from the first electrode, and connected to the second electrode.

2. The device according to claim 1, wherein
the third electrode is formed monolithically with the second electrode.

3. The device according to claim 1, further comprising an insulating film provided between the semiconductor portion and the third electrode.

4. The device according to claim 1, further comprising a fourth electrode arranged in the interior of the semiconductor portion and insulated from the first electrode, the semiconductor portion, the second electrode, and the third electrode, wherein
the third electrode and the fourth electrode are arranged along a direction parallel to an interface between the semiconductor portion and the second electrode.

5. The device according to claim 4, wherein
the third electrode is thicker than the fourth electrode in the parallel direction.

6. The device according to claim 4, wherein
the semiconductor portion includes:
a first layer of a first conductivity type connected to the first electrode;
a second layer of a second conductivity type provided on the first layer;
a third layer of the first conductivity type provided on the second layer and in contact with the second electrode; and
a fourth layer of the second conductivity type provided on a portion of the third layer and in contact with the second electrode,
an intermediate portion of the third electrode is located in the third layer, a lower end portion of the third electrode is located in the second layer,
a portion of an upper end portion of the fourth electrode is located in the fourth layer, an intermediate portion of the fourth electrode is located in the third layer, and a lower end portion of the fourth electrode is located in the second layer.

7. The device according to claim 6, wherein
the third electrode is thicker than the fourth electrode in the parallel direction.

8. The device according to claim 6, wherein
the semiconductor portion further includes a fifth layer of the first conductivity type provided on another portion of the third layer, in contact with the second electrode, and having an effective impurity concentration higher than an effective impurity concentration of the third layer,
a portion of an upper end portion of the third electrode is located in the fourth layer, and another portion of the upper end portion of the third electrode is located in the fifth layer.

9. The device according to claim 4, wherein
the semiconductor portion includes:
a first layer of a first conductivity type connected to the first electrode;
a second layer of a second conductivity type a portion of which is provided on the first layer and another portion of which is connected to the first electrode;
a third layer of the first conductivity type provided on the second layer; and
a fourth layer of the second conductivity type provided on a portion of the third layer and in contact with the second electrode,
an intermediate portion of the third electrode is located in the third layer, a lower end portion of the third electrode is located in the second layer,
a portion of an upper end portion of the fourth electrode is located in the fourth layer, an intermediate portion of the fourth electrode is located in the third layer, and a lower end portion of the fourth electrode is located in the second layer.

10. The device according to claim 9, wherein
the semiconductor portion further includes a fifth layer of the first conductivity type provided on another portion of the third layer, in contact with the second electrode, and having an effective impurity concentration higher than an effective impurity concentration of the third layer,
a portion of an upper end portion of the third electrode is located in the fourth layer, and another portion of the upper end portion of the third electrode is located in the fifth layer.

11. The device according to claim 1, wherein
the semiconductor portion includes:
a first layer of a first conductivity type connected to the first electrode; and
a second layer of a second conductivity type connected to the second electrode.
